(19) United States
(12) Patent Application Publication
(10) Pub. No.: US 2024/0284721 A1
(43) Pub. Date: Aug. 22, 2024

(54) DISPLAY PANEL, DISPLAY DEVICE, AND FABRICATING METHOD FOR DISPLAY PANEL

(71) Applicant: KunShan Go-Visionox Opto Electronics Co., Ltd, Kunshan (CN)

(72) Inventors: Zhimin YAN, Kunshan (CN); Rubo XING, Kunshan (CN); Siming GAO, Kunshan (CN)

(73) Assignee: KunShan Go-Visionox Opto Electronics Co., Ltd, Kunshan (CN)

(21) Appl. No.: 18/650,406

(22) Filed: Apr. 30, 2024

Related U.S. Application Data
(63) Continuation of application No. PCT/CN2022/126259, filed on Oct. 19, 2022.

(30) Foreign Application Priority Data
Aug. 9, 2022 (CN) 202210960550.2

(51) Int. Cl. H10K 59/122; H10K 59/12; H10K 59/173

(52) U.S. Cl. CPC H10K 59/122; H10K 59/1201; H10K 59/173

(57) ABSTRACT

A display panel, a display device, and a fabricating method for a display panel. The display panel includes: a base plate; a first electrode layer located on the base plate, where the first electrode layer includes first electrodes; a pixel definition layer located on a side, away from the base plate, of the first electrode layer and including isolation portions and first openings each of which is enclosed by the isolation portion, at least part of the first electrodes being exposed by the first opening; and a second electrode layer, where at least a portion of the second electrode layer is located on a side, away from the base plate, of the pixel definition layer, the second electrode layer includes body portions and hollow portions penetrating the body portions, and orthogonal projections of the hollow portion and the first electrode on the base plate do not overlap.

### CROSS-REFERENCE TO RELATED APPLICATIONS

This application is a continuation application of International Application No. PCT/CN2022/126259, filed on Oct. 19, 2022, which claims priority to Chinese Patent Application No. 202210960550.2, filed on Aug. 9, 2022, both of which are hereby incorporated by reference in their entireties.

### TECHNICAL FIELD

The present application relates to the field of display, and specifically to a display panel, a display device, and a fabricating method for a display panel.

### BACKGROUND

With the rapid development of electronic devices, users have increasingly high requirements for screen-to-body ratio, so that the full screen display of electronic devices has received increasing attention from the industry.

Conventional electronic devices such as mobile phones and tablets require integration of components such as front cameras, earphones, and infrared sensors. In existing technologies, a notch or hole is formed on a display screen, and external light can enter a photosensitive element located below the screen through the notch or hole on the display screen. However, these electronic devices are not truly full-screen and cannot achieve display in all areas of the entire screen, for example, the corresponding area of the front camera cannot display images.

### SUMMARY

Embodiments of the present application provide a display panel, a display device, and a fabricating method for a display panel to enable at least some areas of the display panel to transmit light and display, thereby facilitating under-screen integration of a photosensitive component.

An embodiment of a first aspect of the present application provides a display panel, including: a base plate; a first electrode layer located on the base plate, where the first electrode layer includes first electrodes; a pixel definition layer located on a side, away from the base plate, of the first electrode layer, where the pixel definition layer includes isolation portions and first openings each of which is enclosed by the isolation portion, and at least part of the first electrode is exposed by the first opening; and a second electrode layer, where at least a portion of the second electrode layer is located on a side, away from the base plate, of the pixel definition layer, the second electrode layer includes body portions and hollow portions penetrating the body portions, and orthogonal projections of the hollow portion and the first electrode on the base plate do not overlap.

According to implementations of the first aspect of the present application, the pixel definition layer further includes second openings penetrating the pixel definition layer, and the orthographic projection of the hollow portion on the base plate is located within an orthographic projection of the second opening on the base plate. This can further shorten the distance between the second electrode layer and the first electrode layer.

According to any of the foregoing implementations of the first aspect of the present application, at least part of edges of the orthographic projection of the first electrode on the base plate are located within the orthographic projection of the second opening on the base plate. This ensures that edges of the body portion are close to the first electrode to better improve the problem of upward folding of the edges of the body portion towards the hollow portion.

According to any of the foregoing implementations of the first aspect of the present application, the first electrode layer further includes second electrodes, orthographic projections of the hollow portion, the second electrode, and the first electrode on the substrate do not overlap, and at least part of edges of the orthographic projection of the second electrode on the base plate are located within the orthographic projection of the second opening on the base plate. With the second electrodes, the first electrode layer can better serve as a mask in a process of ashing the second electrode layer with laser to form the hollow portions without affecting the normal operation of the first electrodes.

According to any of the foregoing implementations of the first aspect of the present application, a maximum distance between the second electrode and the body portion in a thickness direction of the display panel is less than or equal to 0.8 μm. Accordingly, the distance between the first electrode layer and the second electrode layer is relatively short, which can prevent folding of the edges of the body portion towards the hollow portion due to laser diffraction from affecting the packaging effect of a subsequent packaging process.

According to any of the foregoing implementations of the first aspect of the present application, there is a gap between the first electrode and the second electrode. This avoids short-circuit connection of the first electrode through the second electrode and the body portion of the second electrode layer due to interconnection between the second electrode and the body portion of the second electrode layer, which can further improve the yield of the display panel.

According to any of the foregoing implementations of the first aspect of the present application, the first electrodes and the second electrodes are disposed in one-to-one correspondence, and each of the second electrodes surrounds corresponding one first electrode to form an annular gap on circumferential side of the corresponding one first electrode.

According to any of the foregoing implementations of the first aspect of the present application, the gap has a width of 0.5 μm to 10 μm.

According to any of the foregoing implementations of the first aspect of the present application, the isolation portions and the first electrodes are disposed in one-to-one correspondence, the isolation portions are annular, and an orthographic projection of each of the gaps on the base plate is located within an orthographic projection of corresponding one isolation portion on the base plate. The problem of upward folding of the edges of the body portion due to laser diffraction is better improved.

According to any of the foregoing implementations of the first aspect of the present application, the second opening is formed between the two adjacent isolation portions, and edges of orthographic projections of the second electrodes located on two opposite sides of the second opening on the base plate are located within the orthographic projection of the second opening on the base plate.

According to any of the foregoing implementations of the first aspect of the present application, the display panel further includes a metal shielding layer, the metal shielding layer is located on a side, away from the pixel definition layer, of the first electrode layer, the metal shielding layer includes a shielding portion, the orthographic projection of the gap on the base plate is located within an orthographic projection of the shielding portion on the base plate, and the orthographic projection of the hollow portion on the base plate does not overlap the orthographic projection of the shielding portion on the base plate. The shielding portion of the metal shielding layer can shield the laser, so that the second conductive material corresponding to the gap can be retained.

According to any of the foregoing implementations of the first aspect of the present application, the orthographic projection of at least part of the second opening or the orthographic projections of at least some of the second openings on the base plate are located within the orthographic projection of the shielding portion on the base plate.

According to any of the foregoing implementations of the first aspect of the present application, the shielding portion includes:
a plurality of first sub portions extending in a strip shape in a second direction, wherein the plurality of first sub portions are disposed side by side in a first direction; and
a second sub portion extending in the first direction and connected to the plurality of first sub portions, wherein the orthographic projection of at least part of the body portion on the base plate is located within an orthographic projection of the first sub portion on the base plate;
wherein among the plurality of gaps and the plurality of second openings disposed side by side in the second direction, at least part of orthographic projections of each of the gaps and each of the second openings on the base plate are located within the orthographic projection of the same first sub portion on the base plate. Accordingly, the body portions can be connected to each other to form a common electrode on an entire surface.

According to any of the foregoing implementations of the first aspect of the present application, the display panel has a first area and a second area surrounding at least a portion of the first area, the first sub portions are located in the first area, and the second sub portion is located in the second area. This can further reduce the distribution area of the body portions in the first area and improve the transmittance of the first area.

An embodiment of a second aspect of the present application provides a display device, including the display panel in any of the foregoing implementations.

An embodiment of a third aspect of the present application provides a fabricating method for a display panel, including:
fabricating a first conductive material layer on a base plate by coating, and patterning the first conductive material layer to form a first electrode layer, wherein the first electrode layer includes first electrodes;
fabricating an insulating material layer on a side, away from the base plate, of the first electrode layer, and patterning the insulating material layer to form a pixel definition layer, wherein the pixel definition layer includes isolation portions and first openings each of which is enclosed by the isolation portion, and at least part of the first electrode is exposed by the first opening;
fabricating a second conductive material layer on the pixel definition layer; and
etching the second conductive material layer with laser on a side, away from the first electrode layer, of the base plate to form a second electrode layer, where the second electrode layer includes body portions and hollow portions penetrating the body portions, and orthogonal projections of the hollow portion and the first electrode on the base plate do not overlap.

According to the display panel in the embodiments of the present application, the display panel includes a base plate and a first electrode layer, a pixel definition layer, and a second electrode layer disposed on the base plate. The first electrode layer includes first electrodes, the second electrode layer includes body portions and hollow portions, and orthogonal projections of the hollow portion and the first electrode on the base plate do not overlap. In a process of fabricating the second electrode layer, the first electrode layer may be used as a mask, and laser is emitted from the side, away from the first electrode layer, of the base plate towards the second electrode layer to form the hollow portions. On the one hand, the second electrode layer is provided with the hollow portions, which can reduce the distribution area of the body portions, thereby improving the transmittance of the display panel and integrating a photosensitive component on a non-display side of the display panel. On the other hand, one of the first electrode layer and the second electrode layer is disposed on one side of the pixel definition layer, the other is disposed on the other side of the pixel definition layer, and the distance between the first electrode layer and the second electrode layer is relatively short, which can prevent folding of edges of the body portion towards the hollow portion due to laser diffraction from affecting the packaging effect of a subsequent packaging process.

Therefore, in a process of fabricating the display panel in the embodiments of the present application, the first electrode layer can be used as a mask to form the hollow portions on the second electrode layer, thereby improving the transmittance of the display panel and facilitating under-screen integration of the photosensitive component. In addition, the distance between the first electrode layer and the second electrode layer is relatively short, which can prevent folding of the edges of the body portion towards the hollow portion due to laser diffraction, thereby avoiding affecting the packaging effect of the subsequent packaging process.

### DESCRIPTION OF THE DRAWINGS

Other features, objectives, and advantages of the present invention will become more apparent by reading the following detailed descriptions of non-restrictive embodiments with reference to the accompanying drawings, wherein the same or similar reference numerals indicate the same or similar features, and the accompanying drawings are not drawn to actual scale.

FIG. 1 is a schematic structural diagram of a display panel provided in an embodiment of a first aspect of the present application;

FIG. 2 is a cross-sectional view taken along line A-A in FIG. 1;

FIG. 3 is a cross-sectional view taken along line A-A in FIG. 1 in another embodiment;

FIG. 4 is another cross-sectional view taken along line A-A in FIG. 1;

FIG. 5 is a cross-sectional view taken along line A-A in FIG. 1 in another embodiment;

FIG. 6 is a partially enlarged structural diagram at Q in FIG. 1;

FIG. 7 is a cross-sectional view taken along line A-A in FIG. 1 in another embodiment;

FIG. 8 is a partially enlarged structural diagram at Q in FIG. 1 in another embodiment; and

FIG. 9 is a schematic flowchart of a fabricating method for a display panel provided in an embodiment of a third aspect of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the accompanying drawings and specific embodiments. It should be understood that the specific embodiments described herein are only configured to explain the present application, but not configured to limit the present application. For those skilled in the art, the present application can be implemented without some of these specific details. The following descriptions of the embodiments are merely to provide a better understanding of the present invention by showing examples of the present invention.

On an electronic device such as a mobile phone or a tablet computer, a photosensitive component such as a front camera, an infrared light sensor, or a proximity sensor needs to be integrated on a side where a display panel is disposed. In some embodiments, a light-transmitting display area may be disposed on the foregoing electronic device, and the photosensitive component may be disposed on the back of the light-transmitting display area to achieve full screen display of the electronic device while ensuring normal operation of the photosensitive component.

In order to improve the transmittance of the light-transmitting display area, a common electrode is patterned in some related technologies. The common electrode is hollowed in the light-transmitting area of the display panel to improve the transmittance of the common electrode, which can then improve the transmittance of the light-transmitting area of the display panel. In the related technologies, the common electrode is generally patterned by means of laser ashing and the like.

However, when the common electrode is patterned by laser ashing in the related technologies, the common electrode is usually irradiated by laser from a side, away from an array film layer, of a substrate after the array film layer, a light emitting layer, and the common electrode are formed on the substrate, and a shading metal layer in the array film layer is used as a mask to implement laser etching and patterning on the common electrode. After the laser etching and patterning on the common electrode, edges of the common electrode are prone to folding, which will affect subsequent processes such as thin film packaging and affect the reliability of the packaging process.

To solve the above problems, the embodiments of the present application provide a display panel, a display device, and a fabricating method for a display panel. Each embodiment of the display panel, the display device, and the fabricating method for the display panel will be explained below with reference to the accompanying drawings.

An embodiment of the present application provides a display panel. The display panel may be an organic light emitting diode (OLED) display panel.

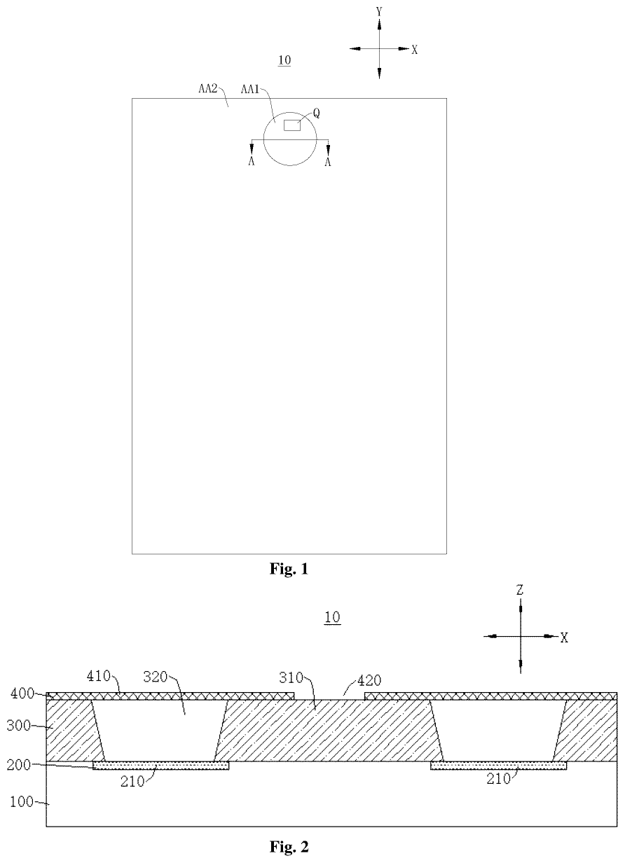

Refer to FIG. 1 and FIG. 2 together, where FIG. 1 is a schematic structural diagram of a display panel 10 provided in an embodiment of a first aspect of the present application, and FIG. 2 is a cross-sectional view taken along line A-A in FIG. 1.

As shown in FIG. 1 and FIG. 2, the display panel 10 provided in the embodiment of the first aspect of the present application includes: a base plate 100, a first electrode layer 200, a pixel definition layer 300, and a second electrode layer 400, where the first electrode layer 200 is located on the base plate 100, and the first electrode layer 200 includes first electrodes 210; the pixel definition layer 300 is located on a side, away from the base plate 100, of the first electrode layer 200, the pixel definition layer 300 includes isolation portions 310 and first openings 320 each of which is enclosed by the isolation portion 310, and at least part of the first electrodes 210 is exposed by the first openings 320; and at least a portion of the second electrode layer 400 is located on a side, away from the base plate 100, of the pixel definition layer 300, the second electrode layer 400 includes body portions 410 and hollow portions 420 penetrating the body portions 410, and orthogonal projections of the hollow portion 420 and the first electrode 210 on the base plate 100 do not overlap.

The embodiment of the present application provides a display panel 10, and the display panel 10 includes a base plate 100 and a first electrode layer 200, a pixel definition layer 300, and a second electrode layer 400 disposed on the base plate 100. The first electrode layer 200 includes first electrodes 210. The pixel definition layer 300 includes first openings 320 and isolation portions 310, light emitting units (not shown) may be disposed in the first openings 320 respectively, and the first electrodes 210 are exposed by the first openings 320, so that the first electrodes 210 can drive the light emitting units in the first openings 320 to emit light. The second electrode layer 400 includes body portions 410 and hollow portions 420, and orthogonal projections of the hollow portions 420 and the first electrodes 210 on the base plate 100 do not overlap, that is, the hollow portions 420 and the first openings 320 are misaligned, which can avoid affecting the display effect of the display panel 10.

When the second electrode layer 400 is fabricated in the display panel 10 provided in the present application, the first electrode layer 200 may be used as a shielding layer, for example, the first electrodes 210 are used as masks, and laser is emitted from a side, away from the first electrode layer 200, of the base plate 100 towards the second electrode layer 400 to etch the second electrode layer 400, so as to form the hollow portions 420. On the one hand, the second electrode layer 400 is provided with the hollow portions 420, which can reduce the distribution area of the body portions 410, thereby improving the transmittance of the display panel 10 and integrating a photosensitive component on a non-display side of the display panel 10. On the other hand, one of the first electrode layer 200 and the second electrode layer 400 is disposed on one side of the pixel definition layer 300, the other is disposed on the other side of the pixel definition layer 300, and the distance between the first electrode layer 200 and the second electrode layer 400 is relatively short, which can reduce or prevent folding of edges of the body portions 410 towards the hollow portions 420 due to laser diffraction from affecting the packaging effect of a subsequent packaging process to further affect the display effect of the display panel 10.

Beneficial effects of the display panel 10 provided in the present application are as follows: On the one hand, the second electrode layer 400 is provided with the hollow portions 420, which can reduce the distribution area of the body portions 410, thereby improving the transmittance of the display panel 10 and integrating a photosensitive component on a non-display side of the display panel 10. On the other hand, one of the first electrode layer 200 and the second electrode layer 400 is disposed on one side of the pixel definition layer 300, the other is disposed on the other side of the pixel definition layer 300, and the distance between the first electrode layer 200 and the second electrode layer 400 is relatively short, which can prevent folding of edges of the body portions 410 towards the hollow portions 420 due to laser diffraction from affecting the packaging effect of a subsequent packaging process.

The base plate 100 may be disposed in various ways, for example, the base plate 100 may include a substrate and an array film layer disposed on the substrate; or the base plate 100 is a substrate; or the base plate 100 further includes a buffer layer and a support plate on a side away from the substrate.

For example, the first electrode layer 200 is an anode layer, and the second electrode layer 400 is a cathode layer. When the first electrode layer 200 and the second electrode layer 400 are used to drive the light emitting units in the first openings 320 to emit light, the first electrode 210 in the first electrode layer 200 serves as an anode, and the body portion 410 of the second electrode layer 400 serves as a cathode.

Optionally, edges of the orthographic projection of the first electrode 210 on the base plate 100 are located within the orthographic projection of the isolation portion 310 on the base plate 100, and the orthographic projection of each first opening 320 on the base plate 100 is located within that of corresponding one first electrode 210 on the base plate 100, which can increase the contact area between the first electrode 210 and the light emitting unit and improve the light emitting effect.

With continued reference to FIG. 1, in some optional embodiments, the display panel 10 has a first display area AA1, a second display area AA2, and a non-display area surrounding the first display area AA1 and the second display area AA2, where the first display area AA1 and the second display area AA2 are display areas, and the transmittance of the first display area AA1 is greater than that of the second display area AA2.

In the present application, the transmittance of the first display area AA1 is optionally greater than or equal to 15%. To ensure that the transmittance of the first display area AA1 is greater than 15%, even greater than 40%, and even higher, in this embodiment, the transmittance of each functional film layer of the display panel 10 located in the first display area AA1 is greater than 80%, and even the transmittances of at least some functional film layers are greater than 90%.

According to the display panel 10 in the embodiments of the present application, if the transmittance of the first display area AA1 is greater than that of the second display area AA2, a photosensitive component may be integrated on a non-display side of the first display area AA1 of the display panel 10 to achieve under-screen integration of the photosensitive component such as a camera. Meanwhile, the first display area AA1 can display images, which increases the display area of the display panel 10 and achieves full screen design of a display device.

Optionally, the hollow portions 420 of the second electrode layer 400 may be located in the first display area AA1 to improve the transmittance of the first display area AA1. In other embodiments, the hollow portions 420 of the second electrode layer 400 may be simultaneously located in the first display area AA1 and the second display area AA2 to improve the transmittance of the entire display area. It may be understood that the hollow portions 420 may be disposed in the first display area AA1 and/or the second display area AA2 in the embodiments provided in the present application, depending on the actual situation.

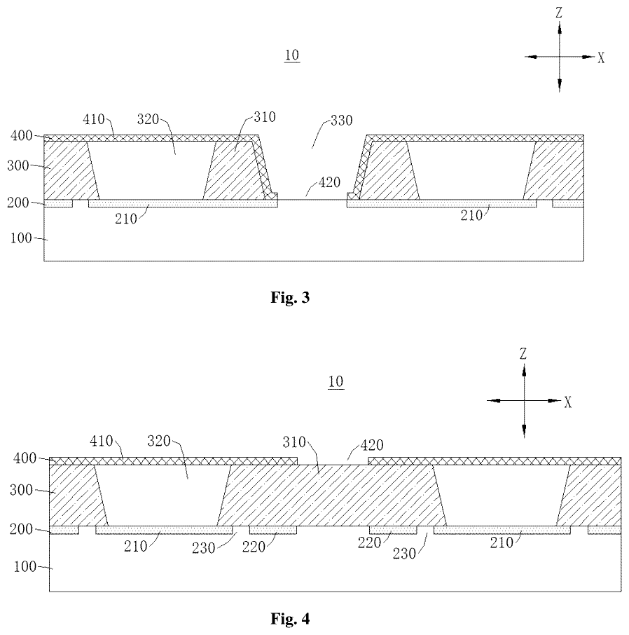

Refer to FIG. 1 and FIG. 3 together, where FIG. 3 is a cross-sectional view taken along line A-A in FIG. 1 in another embodiment.

As shown in FIG. 1 and FIG. 3, in some optional embodiments, the pixel definition layer 300 further includes second openings 330 penetrating the pixel definition layer 300, and the orthographic projection of the hollow portion 420 on the base plate 100 is located within that of the second opening 330 on the base plate 100.

In these optional embodiments, when the second electrode layer 400 is fabricated on the pixel definition layer 300, a second conductive material layer is first formed on the pixel definition layer 300 and then patterned to form the second electrode layer 400. The second conductive material layer can be directly deposited in the second opening 330 to further shorten the distance between the second conductive material layer and the first electrode layer 200.

When the first electrode 210 is used for laser etching and ashing treatment on the second conductive material layer, a hollow portion 420 can be formed in a corresponding area of the second opening 330 to better improve the problem of upward folding of the edges of the body portion 410 towards the hollow portion 420. Specifically, the shorter the distance, the smaller the diffraction, the better the laser focusing effect, so the impact of upward folding of the edges of the body portion 410 on the subsequent packaging process can be better improved.

Optionally, when common layers such as a hole transport layer, a hole injection layer, an electron transport layer, and an electron injection layer are fabricated on the pixel definition layer 300, the common layers are further disposed between the first electrode 210 and the second conductive material layer.

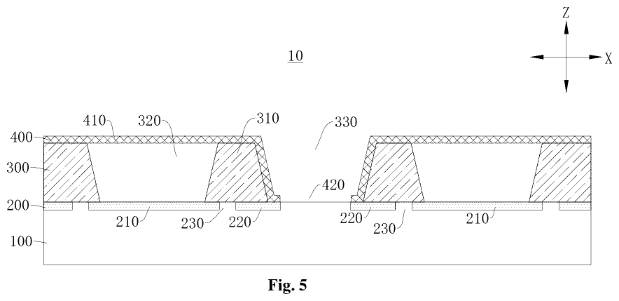

Refer to FIGS. 1, 3, and 4 together, where FIG. 4 is a partially enlarged structural diagram at Q in FIG. 1. In order to better display the structure of the display panel 10 in the present application, FIG. 4 shows only a relative position relationship between the first electrode layer 200 and the pixel definition layer 300.

As shown in FIG. 1 and FIG. 3, in some optional embodiments, at least part of edges of the orthographic projection of the first electrode 210 on the base plate 100 are located within the orthographic projection of the second opening 330 on the base plate 100, that is, at least a portion of the first electrode 210 extends from the isolation portion 310 towards one side of the base plate 100 to the second opening 330.

When the second electrode layer 400 is patterned using the first electrode 210 to form the body portion 410, due to the obstruction of the first electrode 210, the body portion 410 that is not etched is formed in the area where the first electrode 210 is located. At least part of edges of the orthographic projection of the first electrode 210 on the base plate 100 are located within the orthographic projection of the second opening 330 on the base plate 100, which can ensure that the edges of the body portion 410 towards the hollow portion 420 are located within the second opening 330, ensure that the edges of the body portion 410 are closer to the first electrode 210, and better improve the problem of upward folding of the edges of the body portion 410 towards the hollow portion 420.

In some optional embodiments, with reference to FIG. 4, the first electrode layer 200 further includes second electrodes 220, and the orthographic projections of the hollow portion 420, the second electrode 220, and the first electrode 210 on the base plate 100 do not overlap. With the second electrodes 220, the first electrode layer 200 can better serve as a mask in a process of ashing the second electrode layer 400 with laser to form the hollow portions 420 without affecting the normal operation of the first electrodes 210.

Optionally, common layers may not be disposed between the second electrode 220 and the second electrode layer 400 to further shorten the distance between the second electrode 220 and the second electrode layer 400.

With reference to FIG. 5, in some optional embodiments, at least part of edges of the orthographic projection of the second electrode 220 on the base plate 100 are located within the orthographic projection of the second opening 330 on the base plate 100, that is, at least a portion of the second electrode 220 extends from the isolation portion 310 towards one side of the base plate 100 to the second opening 330.

In these embodiments, when the second electrode layer 400 is patterned using the second electrode 220 to form the body portion 410, due to the obstruction of the second electrode 220, the body portion 410 that is not etched is formed in the area where the second electrode 220 is located. At least part of edges of the orthographic projection of the second electrode 220 on the base plate 100 are located within the orthographic projection of the second opening 330 on the base plate 100, which can ensure that the edges of the body portion 410 towards the hollow portion 420 are located within the second opening 330, ensure that the edges of the body portion 410 are closer to the second electrode 220, and better improve the problem of upward folding of the edges of the body portion 410 towards the hollow portion 420.

Optionally, a maximum distance between the second electrode 220 and the body portion 410 in a thickness direction of the display panel 10 is less than or equal to 0.8 μm. Accordingly, the distance between the second electrode 220 and the body portion 410 is shorter, and the problem of upward folding of the edges of the body portion 410 towards the hollow portion 420 is better improved.

Since the first electrode 210 and the second electrode 220 are disposed on the same layer, the maximum distance between the second electrode 220 and the body portion 410 in the thickness direction of the display panel 10 is less than or equal to 0.8 μm. Specifically, the distance between the second electrode 220 and the body portion 410 in the thickness direction of the display panel 10 may be 200 nm, 500 nm, 800 nm, or the like. Accordingly, the distance between the first electrode layer 200 and the body portion 410 is shorter, and the problem of upward folding of the edges of the body portion 410 towards the hollow portion 420 is better improved.

In some optional embodiments, the second electrode 220 and the first opening 320 are misaligned, that is, the orthographic projection of the second electrode 220 on the base plate 100 does not overlap that of the first opening 320 on the base plate 100.

The second electrode 220 is prevented from affecting the light emitting effect of the light emitting unit in the first opening 320.

As shown in FIG. 4 and FIG. 5, in some optional embodiments, there is a gap 230 between the first electrode 210 and the second electrode 220 to avoid short-circuit connection of the first electrode 210 through the second electrode 220 and the body portion 410 of the second electrode layer 400 due to interconnection between the second electrode 220 and the body portion 410 of the second electrode layer 400, which can further improve the yield of the display panel 10. In addition, the second electrode 220 can block laser heat from being transferred to the light emitting unit through the first electrode 210 to affect the display effect.

The gap 230 may be disposed in various sizes. Optionally, the gap 230 has a width of 0.5 μm to 10 μm. Specifically, the width of the gap 230 may be 0.5 μm, 1 μm, 5 μm, or the like, which can improve the short-circuit connection between the second electrode 220 and the body portion 410 due to the excessively small gap 230, and can also improve the formation of a through hole on the second electrode layer 400 corresponding to the gap 230 when the first electrode layer 200 is used as a mask due to the excessively large gap 230, which affect the overlap area of the first electrode 210 and the second electrode layer 400 and affect the light emitting effect of the light emitting unit. It may be understood that the width of the gap 230 refers to a size in a first direction X.

The first electrode 210 and the second electrode 220 are display in various ways, for example, one second electrode 220 may be displayed between two adjacent first electrodes 210.

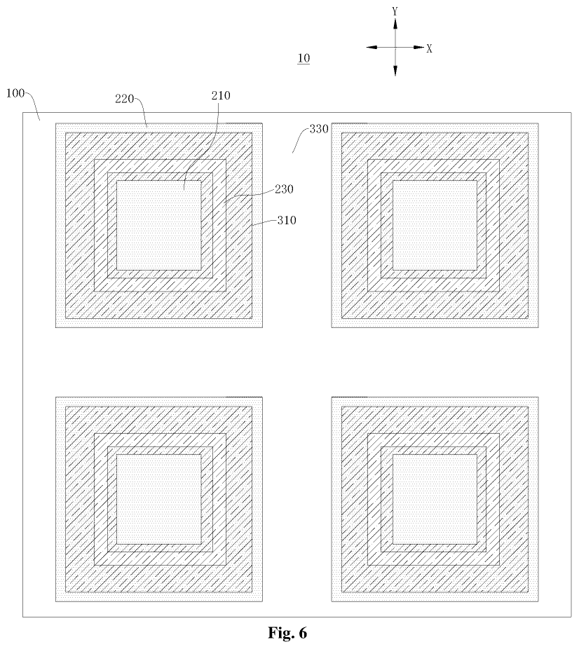

In other optional embodiments, with reference to FIG. 6, the first electrodes 210 and the second electrodes 220 are disposed in one-to-one correspondence, and each second electrode 220 surrounds corresponding one first electrode 210 to form an annular gap 230 on circumferential side of the corresponding one first electrode 210.

In these optional embodiments, each first electrode 210 corresponds to a second electrode 220, and a hollow portion 420 can be formed between the two adjacent second electrodes 220, which can increase the distribution area of the hollow portion 420, reduce the distribution area of the body portion 410, and improve the transmittance of the display panel 10. In addition, the second electrode 220 surrounds the first electrode 210, which can ensure that the hollow portion 420 and the first electrode 210 do not overlap, and prevent the hollow portion 420 from affecting light emission of the light emitting unit in the first opening 320. The annular gap 230 can ensure mutual insulation between the second electrode 220 and the first electrode 210 and avoid short-circuit connection of the first electrode 210 through the second electrode 220 and the body portion 410 of the second electrode layer 400.

In some optional embodiments, as shown in FIG. 6, the isolation portions 310 and the first electrodes 210 are disposed in one-to-one correspondence, the isolation portions 310 are annular, and an orthographic projection of each gap 230 on the base plate 100 is located within that of corresponding one isolation portion 310 on the base plate 100.

In these optional embodiments, the isolation portions 310 are annular, and larger second openings 330 can be formed between the adjacent isolation portions 310, which can further increase the distribution area of the second electrode 220 and the second electrode layer 400 that are closer to each other, and better improve the problem of upward folding of the edges of the body portion 410 due to laser diffraction.

In addition, the orthographic projection of each gap 230 on the base plate 100 is located within that of corresponding one isolation portion 310 on the base plate 100, and the body portions 410 of the second electrode layer 400 is located on a side, away from the first electrode layer 200, of the isolation portion 310, which can ensure mutual insulation between the second electrode layer 400 and the first electrode 210.

Optionally, with continued reference to FIG. 6, the second opening 330 is formed between the two adjacent isolation portions 310, and edges of orthographic projections of the second electrodes 220 located on two opposite sides of the second opening 330 on the base plate 100 are located within the orthographic projection of the second opening 330 on the base plate 100.

For example, when the first electrodes 210 are distributed in an array in a first direction X (X direction in FIG. 6) and a second direction Y (Y direction in FIG. 6), the second electrodes 220 are disposed in the second opening 330 on two sides in the first direction X and two sides in the second direction Y, and the edges of the orthographic projections of the second electrodes 220 in the second opening 330 on the two sides in the first direction X on the base plate 100 are located within the orthographic projection of the second opening 330 on the base plate 100, that is, the edges of the second electrodes 220 in the second opening 330 on the two sides in the first direction X extend into the second opening 330. Similarly, the edges of the second electrodes 220 in the second opening 330 on the two sides in the second direction Y may also extend into the second opening 330 to further increase the distribution area of the second electrode layer 400 and the second electrode 220 closer to each other and better improve the problem of upward folding of the edges of the body portion 410 due to laser diffraction.

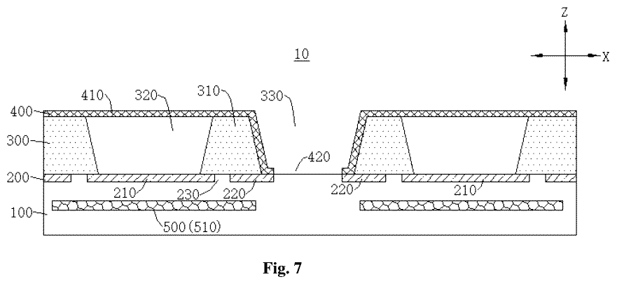

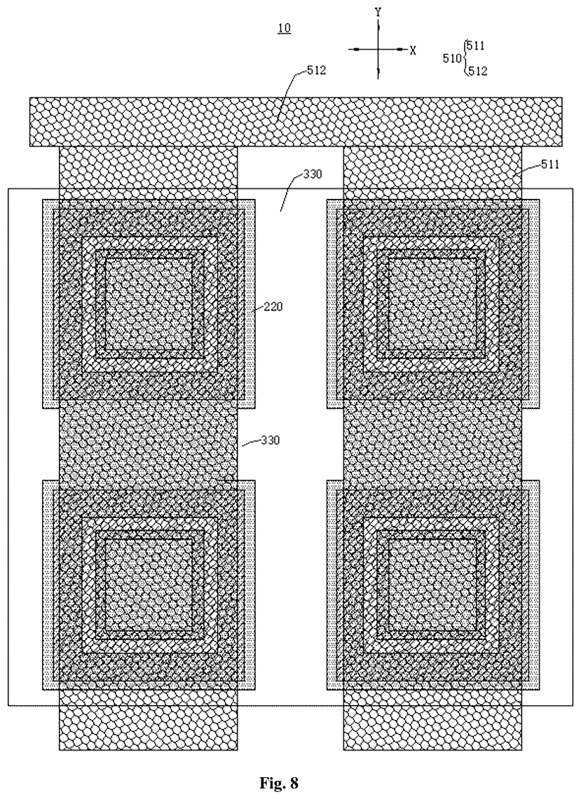

Refer to FIGS. 1, 7, and 8 together, where FIG. 7 is a cross-sectional view taken along line A-A in FIG. 1 in another embodiment, and FIG. 8 is a partially enlarged structural diagram at Q in FIG. 1 in another embodiment.

As shown in FIGS. 1, 7, and 8, in some optional embodiments, the display panel 10 further includes a metal shielding layer 500, the metal shielding layer 500 is located on a side, away from the pixel definition layer 300, of the first electrode layer 200, the metal shielding layer 500 includes a shielding portion 510, the orthographic projection of the gap 230 on the base plate 100 is located within that of the shielding portion 510 on the base plate 100, and the orthographic projection of the hollow portion 420 on the base plate 100 does not overlap that of the shielding portion 510 on the base plate 100.

It may be understood that the orthographic projection of the gap 230 on the base plate 100 is located within that of the shielding portion 510 on the base plate 100, so laser etching and ashing on the second conductive material layer corresponding to the gap 230 may be effectively avoided. It may be understood that the base plate 100 in this embodiment may include an array film layer, and the metal shielding layer 500 may be any metal film layer, as long as it can meet the above requirements.

In an optional embodiment, the orthographic projection of at least part of the second opening 330 on the base plate 100 or the orthographic projections of at least some of the second openings 330 on the base plate 100 are located within that of the shielding portion 510 on the base plate 100, so that the body portions 410 are connected with each other. FIG. 8 illustrates a relative position relationship among the metal shielding layer 500, the first electrode layer 200, and the pixel definition layer 300.

In these optional embodiments, the metal shielding layer 500 is disposed, and when laser is emitted on the side, away from the first electrode layer 200, of the base plate 100 towards the second electrode layer 400, the shielding portion 510 of the metal shielding layer 500 can block the laser, so that the gaps 230 and the second electrode layer 400 corresponding to at least part of the second opening 330 can be retained without being etched, and the body portions 410 can be connected to each other to form an electrode on a whole surface. Therefore, in the presence of the shielding portion 510, the area where the shielding portion 510 is located can form the body portions 410 of at least part of the second electrode layer 400, and the hollow portions 420 of the second electrode layer 400 can be formed in the area where the shielding portion 510 is not located.

“The orthographic projection of at least part of the second opening 330 on the base plate 100 or the orthographic projections of at least some of the second openings 330 on the base plate 100 are located within that of the shielding portion 510 on the base plate 100″ indicates that the orthographic projections of some second openings 330 among the plurality of second openings 330 on the base plate 100 are located within that of the shielding portion 510 on the base plate 100, or the orthographic projection of at least a portion of the same second opening 330 on the base plate 100 is located within that of the shielding portion 510 on the base plate 100, as long as the body portions 410 can be connected to each other.

It may be understood that, in other embodiments, the orthographic projections of at least part of the second electrode 220 on the base plate 100 may be located within that of the shielding portion 510 on the base plate 100, which can ensure that the body portions 410 are connected to each other.

The shielding portion 510 is disposed in various shapes. In some optional embodiments, with continued reference to FIG. 8, the shielding portion 510 includes: a plurality of first sub portions 511 extending in a strip shape in the second direction Y, where the plurality of first sub portions 511 are disposed side by side in the first direction X; and a second sub portion 512 extending in the first direction X and connected to the plurality of first sub portions 511 disposed side by side in the first direction X, where the orthographic projection of at least part of the body portion 410 on the base plate 100 are located within that of the first sub portion 511 on the base plate 100, and among the plurality of gaps 230 and the plurality of second openings 330 disposed side by side in the second direction Y, at least part of orthographic projections of each gap 230 and each second opening 330 on the base plate 100 are located within that of the same first sub portion 511 on the base plate 100.

It may be understood that the first sub portions 511 may be of regular strip structures, such as rectangles, or the first sub portions 511 may be of irregular strip structures, as long as the whole can extend in the second direction Y. A specific shape of the first sub portions 511 is not specified.

In these optional embodiments, the first sub portions 511 can shield at least a portion of each gap 230 among the plurality of gaps 230 in the same row (when the second direction Y is a row direction) and a portion of each second opening 330 among the plurality of second openings 330. Alternatively, the first sub portions 511 can shield at least a portion of each gap 230 among the plurality of gaps 230 in the same column (when the second direction Y is a column direction) and a portion of each second opening 330 among the plurality of second openings 330, so that the body portions 410 in the same row or column can be connected to each other. Through the shielding effect of the second sub portion 512, the body portions 410 distributed in the same area and having the same size as the second sub portion 512 can be formed, so that the body portions 410 at different positions can be connected to each other to form a common electrode on an entire surface.

The second sub portion 512 is disposed in various ways. For example, when the display panel 10 has a first area and a second area surrounding at least a portion of the first area, the first sub portions 511 are located in the first area, and the second sub portion 512 is located in the second area, which can further reduce the distribution area of the body portions 410 in the first area and improve the transmittance of the first area. The second area may be a non-display area, or the second area may be a second display area AA2, which is not limited here.

An embodiment in a second aspect of the present invention further provides a display device, including the display panel 10 in any of the above embodiments of the first aspect. Since the display device provided in the embodiment of the second aspect of the present invention includes the display panel 10 in any of the above embodiments of the first aspect, the display device provided in the embodiment of the second aspect of the present invention has the beneficial effects of the display panel 10 in any of the above embodiments of the first aspect, and details will not be repeated here.

The display device in the embodiment of the present invention includes but is not limited to devices with display functions, such as a mobile phone, a personal digital assistant (PDA), a tablet computer, an e-book, a television, an access control, an intelligent fixed-line telephone, and a console.

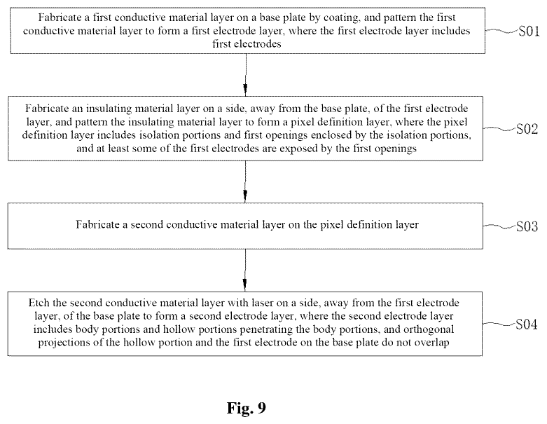

Refer to FIG. 9. FIG. 9 is a schematic flowchart of a fabricating method for a display panel 10 provided in an embodiment of a third aspect of the present application. The display panel 10 may be the display panel 10 provided in any of the above embodiments of the first aspect.

As shown in FIG. 9, with reference to the display panel 10 shown in FIGS. 1 to 8, the fabricating method for the display panel 10 includes:

Step S01: Fabricate a first conductive material layer on a base plate by coating, and pattern the first conductive material layer to form a first electrode layer, where the first electrode layer includes first electrodes.

Step S02: Fabricate an insulating material layer on a side, away from the base plate, of the first electrode layer, and pattern the insulating material layer to form a pixel definition layer, where the pixel definition layer includes isolation portions and first openings each of which is enclosed by the isolation portion, and at least part of the first electrode is exposed by the first openings.

Optionally, layer structures such as a hole injection layer, a hole transport layer, light emitting units, an electron transport layer, and an electron injection layer may be further disposed on the pixel definition layer 300 after step S02.

Step S03: Fabricate a second conductive material layer on the pixel definition layer.

Step S04: Etch the second conductive material layer with laser on a side, away from the first electrode layer, of the base plate to form a second electrode layer, where the second electrode layer includes body portions and hollow portions penetrating the body portions, and orthogonal projections of the hollow portion and the first electrode on the base plate do not overlap.

In the fabricating method for the display panel 10 provided in the embodiments of the present application, the first electrodes 210 are first formed through step S01, the first electrodes 210 may serve as masks for patterning the second conductive material layer in step S03, and the second conductive material layer in areas where the first electrodes 210 are located are not etched off but form the body portions 410 of the second electrode layer 400. Then, the pixel definition layer 300 is formed through step S02, so that the light emitting units can be disposed in the first openings 320, and the first electrodes 210 and the body portions 410 of the second electrode layer 400 can drive the light emitting units to emit light. Since the first electrodes 210 serve as masks for patterning the second conductive material layer, the material of the second conductive material layer in the areas where the first electrodes 210 are not located is etched off by laser. Therefore, the orthographic projections of at least part of the body portion 410 of the second electrode layer 400 and the first electrode 210 in the thickness direction overlap, and orthogonal projections of the hollow portion 420 and the first electrode 210 on the base plate 100 do not overlap.

In some optional embodiments, in step S02, the insulating material layer may be further patterned to form second openings 330. Since light emitting units are not disposed in the second openings 330, when common layers such as a hole injection layer, a hole transport layer, an electron transport layer, and an electron injection layer are disposed on the pixel definition layer 300, the common layers can be directly deposited on the first electrodes 210 in the second openings 330. When the second conductive material layer is formed in step S03, layer structures such as common layers are disposed between the second conductive material layer and the first electrode 210, but structures such as isolation portions 310 are not disposed there, which can further shorten the distance between the second conductive material layer and the first electrodes 210 in the areas where the second openings 330 are located. When the second conductive material layer is patterned with the first electrodes 210 as masks in step S04, diffraction can be improved, and upward folding of edges of the body portions 410 can be prevented from affecting the yield of a subsequent packaging process.

In some optional embodiments, the first electrode layer 200 further includes second electrodes 220, the orthographic projections of the hollow portion 420, the second electrode 220, and the first electrode 210 on the base plate 100 do not overlap, at least part of edges of the orthographic projection of the second electrode 220 on the base plate 100 are located within the orthographic projection of the second opening 330 on the base plate 100, and a gap 230 is further disposed between the second electrode 220 and the first electrode 210 to avoid short-circuit connection of the body portion 410 of the second electrode layer 400 through the second electrode 220 and the first electrode 210.

In some optional embodiments, before step S01, a metal shielding layer 500 may be first formed, where the metal shielding layer 500 includes a shielding portion 510. Specifically, an orthographic projection of the gap 230 on the base plate 100 may be located within that of the shielding portion 510 on the base plate 100. Optionally, the orthographic projections of the gaps 230 and at least part of the second opening 330 on the base plate 100 may be located within that of the shielding portion 510 on the base plate 100. In the presence of the shielding portion 510, when the second conductive material layer is patterned by laser in step S04, the shielding portion 510 can shield the laser, so that the second conductive material layer in the area where the shielding portion 510 is located will not be etched off. Therefore, no hollow portion 420 is formed in the area where the shielding portion 510 is located, and the orthogonal projection of the hollow portion 420 on the base plate 100 does not overlap that of the shielding portion 510 on the base plate 100.

The shielding portion 510 may be disposed in various positions, as long as the body portions 410 can be connected to each other in the presence of the shielding portion 510. As mentioned above, the shielding portion 510 may include first sub portions 511 and a second sub portion 512.

According to the embodiments described above in the present application, these embodiments do not fully describe all details, and the present invention is not limited to the described specific embodiments. Apparently, many modifications and changes may be made to the above description. This specification selects and specifically describes these embodiments in order to better explain the principles and practical applications of the present application, so that those skilled in the art can make good use of the present application and modifications based on the present application. The present application is merely limited by the claims and all their scope and equivalents.

What is claimed is:

1. A display panel, comprising:
a base plate;
a first electrode layer located on the base plate, wherein the first electrode layer comprises first electrodes;
a pixel definition layer located on a side, away from the base plate, of the first electrode layer, wherein the pixel definition layer comprises isolation portions and first openings each of which is enclosed by the isolation portion, and at least part of the first electrode is exposed by the first opening; and
a second electrode layer, wherein at least a portion of the second electrode layer is located on a side, away from the base plate, of the pixel definition layer, the second electrode layer comprises body portions and hollow portions penetrating the body portions, and orthogonal projections of the hollow portion and the first electrode on the base plate do not overlap.

2. The display panel according to claim 1, wherein the pixel definition layer further comprises second openings penetrating the pixel definition layer, and the orthographic projection of the hollow portion on the base plate is located within an orthographic projection of the second opening on the base plate.

3. The display panel according to claim 2, wherein at least part of edges of the orthographic projection of the first electrode on the base plate are located within the orthographic projection of the second opening on the base plate.

4. The display panel according to claim 2, wherein the first electrode layer further comprises second electrodes, orthographic projections of the hollow portion, the second electrode, and the first electrode on the substrate do not overlap, and at least part of edges of the orthographic projection of the second electrode on the base plate are located within the orthographic projection of the second opening on the base plate.

5. The display panel according to claim 4, wherein a maximum distance between the second electrode and the body portion in a thickness direction of the display panel is less than or equal to 0.8 μm.

6. The display panel according to claim 4, wherein there is a gap between the first electrode and the second electrode.

7. The display panel according to claim 6, wherein the first electrodes and the second electrodes are disposed in one-to-one correspondence, and each of the second electrodes surrounds corresponding one first electrode to form an annular gap on circumferential side of the corresponding one first electrode.

8. The display panel according to claim 6, wherein the gap has a width of 0.5 μm to 10 μm.

9. The display panel according to claim 6, wherein the isolation portions and the first electrodes are disposed in one-to-one correspondence, the isolation portions are annular, and an orthographic projection of each of the gaps on the base plate is located within an orthographic projection of corresponding one isolation portion on the base plate.

10. The display panel according to claim 4, wherein the second opening is formed between the two adjacent isolation portions, and edges of orthographic projections of the second electrodes located on two opposite sides of the second opening on the base plate are located within the orthographic projection of the second opening on the base plate.

11. The display panel according to claim 4, wherein the orthographic projection of the second electrode on the base plate does not overlap that of the first opening on the base plate.

12. The display panel according to claim 6, wherein the display panel further comprises a metal shielding layer, the metal shielding layer is located on a side, away from the pixel definition layer, of the first electrode layer, the metal shielding layer comprises a shielding portion, an orthographic projection of the gap on the base plate is located within an orthographic projection of the shielding portion on the base plate, and the orthographic projection of the hollow portion on the base plate does not overlap the orthographic projection of the shielding portion on the base plate.

13. The display panel according to claim 12, wherein the orthographic projection of at least part of the second opening on the base plate or the orthographic projections of at least some of the second openings on the base plate are located within the orthographic projection of the shielding portion on the base plate.

14. The display panel according to claim 12, wherein the shielding portion comprises:
a plurality of first sub portions extending in a strip shape in a second direction, wherein the plurality of first sub portions are disposed side by side in a first direction; and
a second sub portion extending in the first direction and connected to the plurality of first sub portions, wherein the orthographic projection of at least part of the body portion on the base plate is located within an orthographic projection of the first sub portion on the base plate;
wherein among the plurality of gaps and the plurality of second openings disposed side by side in the second direction, at least part of orthographic projections of each of the gaps and each of the second openings on the base plate are located within the orthographic projection of the same first sub portion on the base plate.

15. The display panel according to claim 14, wherein the display panel has a first area and a second area surrounding at least a portion of the first area, the first sub portions are located in the first area, and the second sub portion is located in the second area.

16. A display device, wherein the display device comprises the display panel according to claim 1.

17. A fabricating method for a display panel, comprising:
fabricating a first conductive material layer on a base plate by coating, and patterning the first conductive material layer to form a first electrode layer, wherein the first electrode layer comprises first electrodes;
fabricating an insulating material layer on a side, away from the base plate, of the first electrode layer, and patterning the insulating material layer to form a pixel definition layer, wherein the pixel definition layer comprises isolation portions and first openings each of which is enclosed by the isolation portion, and at least part of the first electrode is exposed by the first opening;
fabricating a second conductive material layer on the pixel definition layer; and
etching the second conductive material layer with laser on a side, away from the first electrode layer, of the base plate to form a second electrode layer, wherein the second electrode layer comprises body portions and hollow portions penetrating the body portions, and orthogonal projections of the hollow portion and the first electrode on the base plate do not overlap.
